(19) United States
(12) Patent Application Publication
(10) Pub. No.: US 2012/0125678 A1
(43) Pub. Date: May 24, 2012

(54) Electrical Connector

(75) Inventor: Arturo Caines, Hanover Park, IL (US)

(73) Assignee: Cinch Connectors, Inc., Lombard, IL (US)

(21) Appl. No.: 12/953,248

(22) Filed: Nov. 23, 2010

(51) Int. Cl. H05K 1/11

(52) U.S. Cl. 174/262

(57) ABSTRACT

The electrical connector may include one or more contacts and a contact substrate. The contact may include a wadded wire element and a sleeve. The electrical connector may be used to connect a first electrical component to a second electrical component. The electrical components may be integrated circuit chip packages, printed circuit boards, wire contacts, headers, and wiring harnesses. The contact which includes the sleeve is able to provide more electrical power at a given temperature than the contact which includes the wadded wire element but not the sleeve. The sleeve may include an element retention feature. The element retention feature may help retain the wadded wire element within the sleeve. The sleeve may include a sleeve retention feature. The sleeve retention feature may help retain the sleeve within the contact substrate.

### BACKGROUND OF THE INVENTION

Electrical connectors may be used to connect one component with another component. For example, electrical connectors may be used to provide a conductive path between contact pads on an integrated circuit package and conductive traces on a substrate, such as a printed circuit board. As another example, a first printed circuit board may be connected to a second printed circuit board. As a further example, a wiring harness may be connected to a printed circuit board.

### BRIEF SUMMARY OF THE INVENTION

The electrical connector may include one or more contacts and a contact substrate. The contact may include a wadded wire element and a sleeve. The electrical connector may be used to connect a first electrical component to a second electrical component. The electrical components may be integrated circuit chip packages, printed circuit boards, wire contacts, headers, and wiring harnesses. The contact which includes the sleeve is able to provide more electrical power at a given temperature than the contact which includes the wadded wire element but not the sleeve. The sleeve may include an element retention feature. The element retention feature may help retain the wadded wire element within the sleeve. The sleeve may include a sleeve retention feature. The sleeve retention feature may help retain the sleeve within the contact substrate.

### BRIEF DESCRIPTION OF THE DRAWINGS

FIG. 1 is a perspective view of an electrical connector.

FIG. 2 is a partial cross-sectional view of the electrical connector in FIG. 1.

FIG. 3 is a cross sectional view of the electrical connector being used in a particular application.

FIG. 4 is a perspective view of another embodiment of the electrical contact.

FIG. 5 is a cross sectional view of an electrical connector with the electrical contact in FIG. 4.

FIG. 6 is a perspective view of another embodiment of an electrical contact.

FIG. 7 is a cross sectional view of another embodiment of an electrical connector.

FIG. 8 is a cross sectional view of another embodiment of an electrical connector.

FIG. 9 is a cross sectional view of another embodiment of an electrical contact.

FIG. 10 is a cross sectional view of another embodiment of an electrical contact.

FIG. 11 is a cross sectional view of another embodiment of an electrical connector.

FIG. 12 is a cross sectional view of another embodiment of an electrical connector.

FIG. 13 is a cross sectional view of another embodiment of an electrical connector.

FIG. 14 is a cross sectional view of another embodiment of an electrical connector.

FIG. 15 a cross sectional view of is another embodiment of an electrical connector.

FIG. 16 is a cross sectional view of another embodiment of an electrical connector.

FIG. 17 is a cross sectional view of another embodiment of an electrical connector.

FIG. 18 is a cross sectional view of another embodiment of an electrical connector.

FIG. 19 is a cross sectional view of another embodiment of an electrical connector.

FIG. 20 is a cross sectional view of another embodiment of an electrical connector.

FIG. 21 is a cross sectional view of another embodiment of an electrical connector.

FIG. 22 is a cross sectional view of another embodiment of an electrical connector.

FIG. 23 is a cross sectional view of another embodiment of an electrical connector.

FIG. 24 is a cross sectional view of another embodiment of an electrical connector.

FIG. 25 is a cross sectional view of another embodiment of an electrical connector.

FIG. 26 is a cross sectional view of another embodiment of an electrical connector.

FIG. 27 is a cross sectional view of another embodiment of an electrical connector.

FIG. 28 is a cross sectional view of another embodiment of an electrical connector.

FIG. 29 is a cross sectional view of another embodiment of an electrical connector.

FIG. 30 is a cross sectional view of another embodiment of an electrical connector.

FIG. 31 is a cross sectional view of another embodiment of an electrical connector.

FIG. 32 is a cross sectional view of another embodiment of an electrical connector.

FIG. 33 is a cross sectional view of another embodiment of an electrical connector.

FIG. 34 is a cross sectional view of another embodiment of an electrical connector.

FIG. 35 is a cross sectional view of another embodiment of an electrical connector.

### DETAILED DESCRIPTION OF THE INVENTION

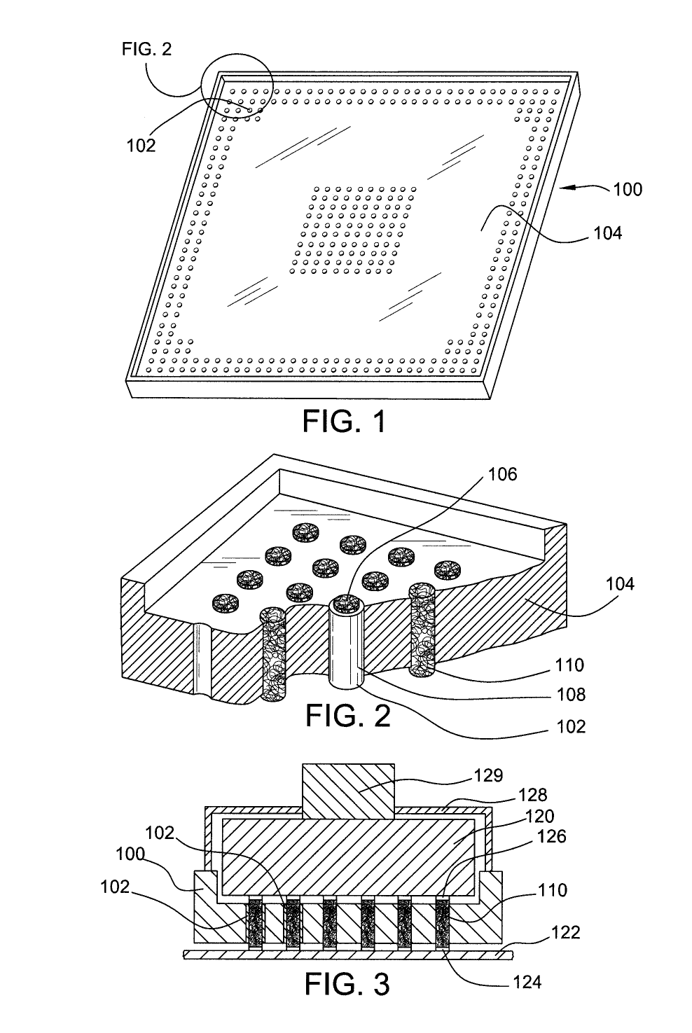

Referring to FIGS. 1 and 2, an electrical connector 100 is shown. The electrical connector 100 may include one or more contacts 102 and a contact substrate 104. The contact 102 may include a wadded wire element 106 and a sleeve 108. The wadded wire element may be a resiliently wadded conductor, typically in the form of an elongated cylindrical contact element comprising a resiliently and randomly wadded single thin gauge electrically conductive wire. The wadded wire element may be available from Cinch Connectors, Inc., of Lombard, Ill., USA under the tradename CIN::APSE. The wadded wire element may be similar to the contacts 12 in U.S. Pat. No. 4,988,306. The electrical connector 100 may include other contacts 110 which may not include the sleeve.

The electrical connector may be used to connect a first electrical component to a second electrical component. The electrical components may be various electrical components, such as, integrated circuit chip packages, printed circuit boards, wire contacts, headers, and wiring harnesses. In one embodiment, an IC chip package may be connected to a printed circuit board. In another embodiment, a first printed circuit board may be connected to a second printed circuit board. In yet another embodiment, a wiring harness may be connected to a printed circuit board.

Referring to FIG. 3, in one embodiment, the electrical connector 100 may be used to connect an integrated circuit chip package 120 to a substrate 122, such as, a printed circuit board. The substrate 122 may include one or more contact areas 124. The IC chip package 120 may include one or more contact areas 126. The electrical connector may include one or more contacts 102. The electrical connector may include one or more contacts 110. The contact 102 connects the contact areas 124 to the contact areas 126. The contact 102 may transmit electrical power from the substrate 122 to the IC chip package 120. The contact 102 which includes the sleeve 108 is able to provide more electrical power at a given temperature than the contact 110 (which includes the wadded wire element but not the sleeve). The contact 110 may be used to transmit electrical signals. The electrical assembly may include a clamp 128 to hold the IC chip package 120 onto the contact substrate 104. The electrical assembly may include a heat sink 129 to remove heat from the IC chip package 120.

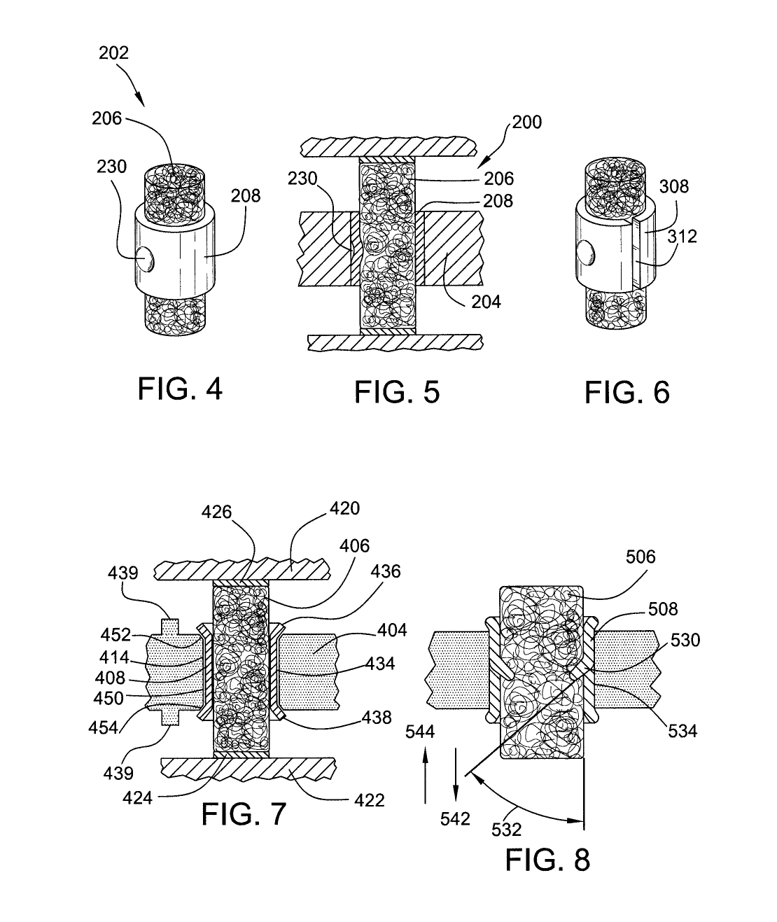

Referring to FIGS. 4 and 5, the sleeve may include an element retention feature. The element retention feature may help retain the wadded wire element within the sleeve. In one embodiment, the element retention feature may be a detent 230. The detent 230 may help to retain the wadded wire element 206 within the sleeve 208 by narrowing the sleeve. The narrowing of the sleeve at the detent 230 may limit the movement of the element 206 in the area of the detent 230. In one embodiment, the sleeve 208 may be press fit into the substrate 204. In other embodiments, the connector 200 may use any of the sleeve retention features described herein, as appropriate.

The sleeve may include a sleeve retention feature. The sleeve retention feature may help retain the sleeve within the contact substrate. Referring to FIG. 6, the sleeve 308 may have a sleeve retention feature. In this embodiment, the sleeve retention feature may be a gap 312. The sleeve 308 may be compressed to close the gap 312 and then inserted into an opening in the contact substrate. After the sleeve 308 is inserted into the opening, the sleeve 308 is allowed to relax and the sleeve expands inside the opening to be held in the contact substrate. The opening in the contact substrate may be slightly smaller than the outside dimension of the sleeve in the relaxed state. In other embodiments, the contact may use any of the element retention features described herein, as appropriate.

Referring to FIG. 7, another embodiment is shown. In this embodiment, the sleeve retention feature may be the first and second end portions 436, 438 which may be larger than the main portion 434 of the sleeve 408. The sleeve 408 may be inserted into an opening 414 in the substrate 404. In this embodiment, the first end portion 436 and the second end portion 438 may be flared outwards in order to retain the sleeve 408 in the opening 414 in the contact substrate 404. The wadded wire element 406 may then be inserted into the sleeve 408. In one embodiment, the first end portion 436 and the second end portion 438 may be formed after insertion of the sleeve into the opening 414. In another embodiment, the first end portion 436 may be formed prior to insertion in the opening 414, and the second end portion 438 may be formed after insertion in opening 414. In one embodiment, the first end portion 436 and/or the second end portion 438 may extend beyond the upper and lower surfaces of the contact substrate 404.

In one embodiment, the substrate 404 may include one or more standoffs 439. The upper standoff 439 may prevent the sleeve 408 from contacting the contact area 426 on the first component 420. The lower standoff 439 may prevent the sleeve 408 from contacting the contact area 424 on the second component 422. In another embodiment, the substrate may include the upper standoff, but not the lower standoff. In another embodiment, the substrate may include the lower standoff, but not the upper standoff. In another embodiment, the substrate may not include the upper and lower standoffs. The standoff feature may be used with any of the embodiments described herein, as appropriate.

The opening 414 may include a main portion 450, a first end portion 452, and a second end portion 454. The first end portion 452 may be larger than the main portion 450. The second end portion 454 may be larger than the main portion 450. The end portions 452, 454 may be a chamfer or a countersink. In another embodiment, the opening may include a first end portion, but not a second end portion. In another embodiment, the opening may include a second end portion, but not a first end portion. In another embodiment, the opening may not include the first and second end portions. In other embodiments, the connector may use any of the element retention features described herein, as appropriate.

Referring to FIG. 8, another embodiment is shown. In this embodiment, the element retention feature may be a barb 530. The sleeve 508 may include one or more barbs 530 to retain the wadded wire element 506. The barb 530 may extend inward from the main portion 534 of the sleeve. The barbs 530 may engage the wadded wire element 506. The wire in the wadded wire element 506 may become caught in the barbs 530 in order to prevent removal of the element 506 from the sleeve 508. The barbs 530 may be at an angle 532 to the main portion 534 of the sleeve 508. In one embodiment, the angle may be at 45 degrees. The angle may permit the insertion of the wadded wire element in one direction, such as, direction 542, and prevent the removal of the wadded wire element in the other direction, such as, direction 544. In other embodiments, the angle may be at other degrees, such as, 30 degrees, or 15 degrees. In another embodiment, the angle may be at 90 degrees which may prevent the removal of the wadded wire element in either direction, such as, the barb 830 in FIG. 11. The wadded wire element may be difficult to insert with the barb at a 90 degree angle. Thus, the barb may be formed after the insertion of the wadded wire element. In other embodiments, the connector may use any of the sleeve retention features described herein, as appropriate.

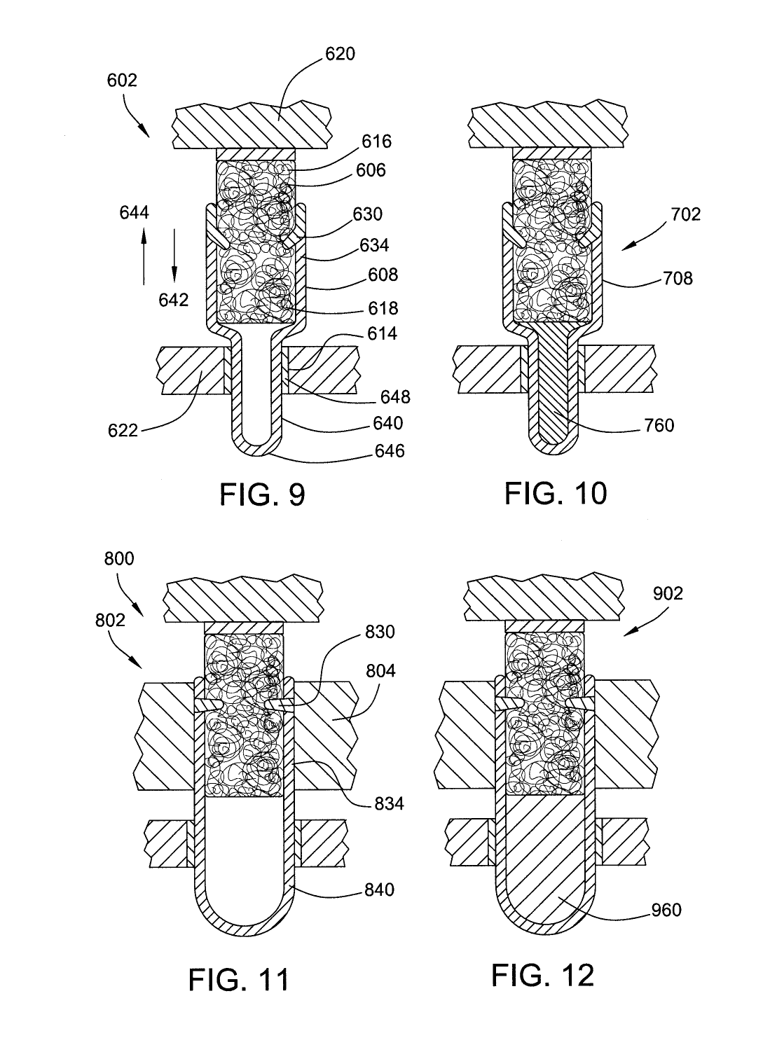

Referring to FIG. 9, another embodiment is shown. In this embodiment, the sleeve 608 may have an extension portion 640 which may extend beyond the second end 618 of the element 606. The first end 616 of the element 606 may extend beyond the main portion 634 of the sleeve. The sleeve 608 may have a closed end 646. The extension portion 640 may be smaller than the main portion 634. The narrow extension portion 640 may prevent the element 606 from moving further into the sleeve 608 in direction 642. The sleeve 608 may include barbs 630 to prevent the element from being removed from the sleeve 608 in direction 644. In other embodiments, the contact 602 may use any of the element retention features described herein, as appropriate.

The sleeve 608 may be positioned in a contact opening 614 which has a conductive lining 648. The conductive lining 648 may be a metal plating. After the sleeve 608 has been inserted into the opening 614, the sleeve 608 may be soldered to the conductive lining 648, such as, by a reflow soldering process. The solder may be a sleeve retention feature. In other embodiments, the sleeve 608 may be press fit into the conductive lining 648. The press fit may be a sleeve retention feature. The contact 602 may provide an electrical connection between a first component 620, such as a printed circuit board, and a second component 622, such as a printed circuit board.

Referring to FIG. 10, the contact 702 may be similar to contact 602 except that the contact 702 may include a conductive material 760 within the sleeve 708. The conductive material 760 may be a slug, particles, a gel, or a fluid. The conductive material 760 may allow the contact to provide more electrical power at a given temperature than the contact without the conductive material. In other embodiments, the contact may use any of the element retention features described herein, as appropriate.

Referring to FIG. 11, the contact 802 may be similar to contact 602 except that the contact 802 may have an extension portion 840 which may be the same size as the main portion 834. The electrical connector 800 may include a contact substrate 804. The contact 802 may include barbs 830. The barbs 830 may be at 90 degrees to the main portion 834. In other embodiments, the connector 800 may use any of the element retention features described herein, as appropriate.

Referring to FIG. 12, the contact 902 may be similar to contact 802 except that the contact 902 may include a conductive material 960, as described herein. In other embodiments, the connector may use any of the element retention features described herein, and/or any of the sleeve retention features described herein, as appropriate.

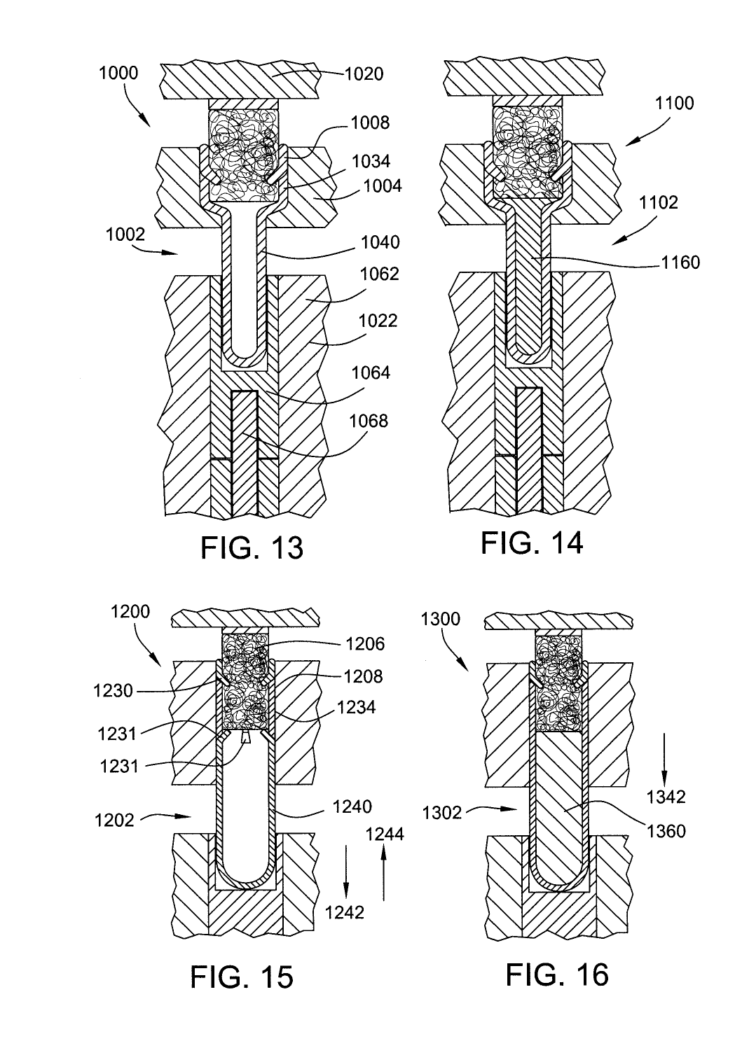

Referring to FIG. 13, the contact 1002 may be similar to contact 602 except that the main portion 1034 of the sleeve 1008 may be shorter and the extension portion 1040 may be longer than the contact 602. The electrical connector 1000 may include a contact substrate 1004. The sleeve 1008 may have a sleeve retention feature, such as, being press fit into the substrate 1004, or being molded into the substrate 1004. The electrical connector 1000 may provide an electrical connection between a first component 1020, such as, a printed circuit board, and a second component 1022, such as, a wiring harness. The wiring harness 1022 may include an insulator 1062, one or more contacts 1064, and one or more wires 1068. In other embodiments, the connector may use any of the element retention features described herein, and/or any of the sleeve retention features described herein, as appropriate.

Referring to FIG. 14, the connector 1100 may be similar to connector 1000 except that contact 1102 may include a conductive material 1160, as described herein. In other embodiments, the connector may use any of the element retention features described herein, and/or any of the sleeve retention features described herein, as appropriate.

Referring to FIG. 15, the connector 1200 may be similar to connector 1000 except that the contact 1202 may have an extension portion 1240 which may be the same size as the main portion 1234, and the contact 1202 may include one or more second barbs 1231. The second barbs 1231 may prevent the element 1206 from moving further into the sleeve 1208 in direction 1242. The barbs 1230 may prevent the element 1206 from being removed in direction 1244. In other embodiments, the connector may use any of the sleeve retention features described herein, as appropriate.

Referring to FIG. 16, the connector 1300 may be similar to connector 1200 except that the contact 1302 may include a conductive material 1360, as described herein, and the contact 1302 may not include the second barbs 1231. The second barbs 1231 may not be needed because the conductive material 1360 may prevent the element from being moved in direction 1342. In other embodiments, the connector may use any of the element retention features described herein, and/or any of the sleeve retention features described herein, as appropriate.

Referring to FIG. 17, the connector 1400 may be similar to connector 1000 except that the extension portion 1440 may be bent at an angle 1441. In one embodiment, the angle 1441 may be approximately 90 degrees. The contact substrate 1404 may be one or more components in order to facilitate assembly. The electrical connector 1400 may provide an electrical connection between a first component 1420, such as, a printed circuit board, and a second component 1422, such as, a wiring harness. In other embodiments, the connector may use any of the element retention features described herein, as appropriate.

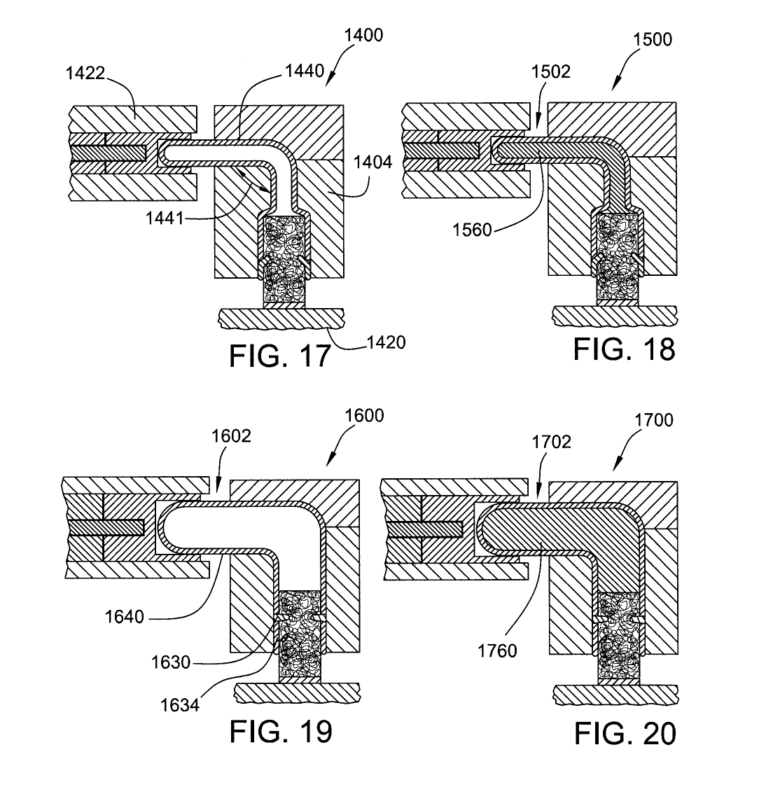

Referring to FIG. 18, the connector 1500 may be similar to connector 1400 except that the contact 1502 may include a conductive material 1560, as described herein. In other embodiments, the connector may use any of the element retention features described herein, as appropriate.

Referring to FIG. 19, the connector 1600 may be similar to connector 1400 except that the contact 1602 may have an extension portion 1640 which may be the same size as the main portion 1634, and the 1602 may include barbs 1630 at an angle of approximately 90 degrees to the main portion 1634. In other embodiments, the connector may use any of the element retention features described herein, as appropriate.

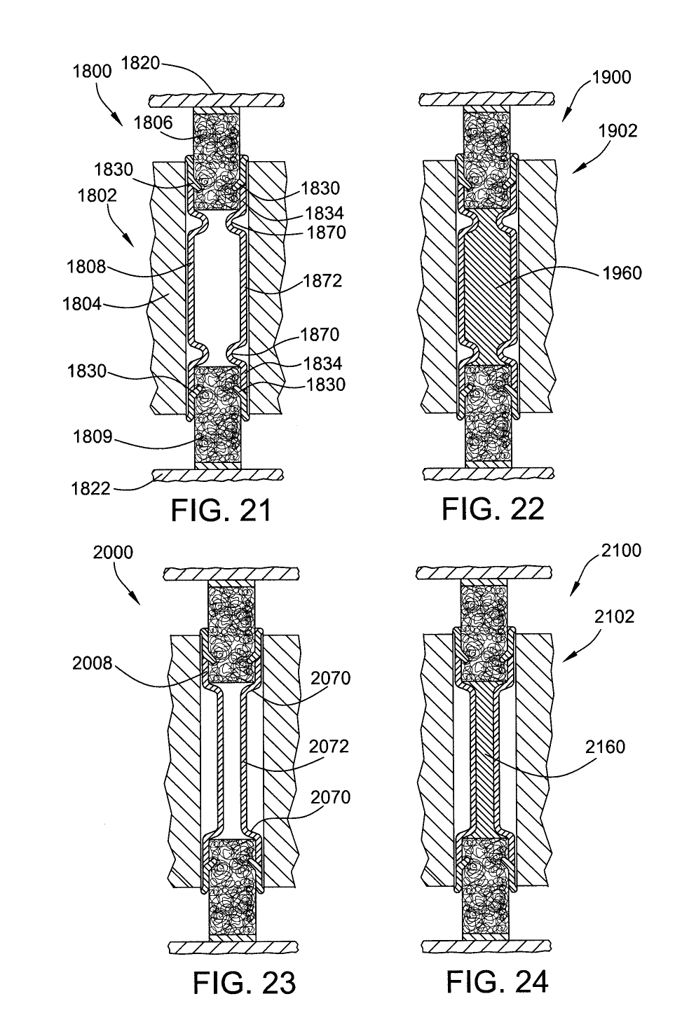

Referring to FIG. 20, the connector 1700 may be similar to connector 1600 except that the contact 1702 may include a conductive material 1760, as described herein. In other embodiments, the connector may use any of the element retention features described herein, as appropriate.

Referring to FIG. 21, another embodiment of a connector is shown. In this embodiment, the connector may be used for longer distances. The connector 1800 may include a contact 1802 and a contact substrate 1804. The contact 1802 may include a wadded wire element 1806, a sleeve 1808, and a second wadded wire element 1809. The contact 1802 may utilize narrowed portions 1870 and barbs 1830 to retain the elements 1806, 1809 to the sleeve 1808. In one embodiment, the narrowed portions 1870 may be smaller than the main portion 1834. Also, the contact 1802 may include an intermediate portion 1872 which may be the same size as the main portion 1834. The electrical connector 1800 may provide an electrical connection between a first component 1820, such as a printed circuit board, and a second component 1822, such as, a printed circuit board. In other embodiments, the connector may use any of the element retention features described herein, and/or any of the sleeve retention features described herein, as appropriate.

Referring to FIG. 22, the connector 1900 may be similar to connector 1800 except that the contact 1902 may include a conductive material 1960, as described herein. In other embodiments, the connector may use any of the element retention features described herein, and/or any of the sleeve retention features described herein, as appropriate.

Referring to FIG. 23, the connector 2000 may be similar to connector 1800 except that the intermediate portion 2072 of the sleeve 2008 may be the same size as the narrowed portions 2070. In other embodiments, the connector may use any of the element retention features described herein, and/or any of the sleeve retention features described herein, as appropriate.

Referring to FIG. 24, the connector 2100 may be similar to connector 2000 except that the contact 2102 may include a conductive material 2160, as described herein. In other embodiments, the connector may use any of the element retention features described herein, and/or any of the sleeve retention features described herein, as appropriate.

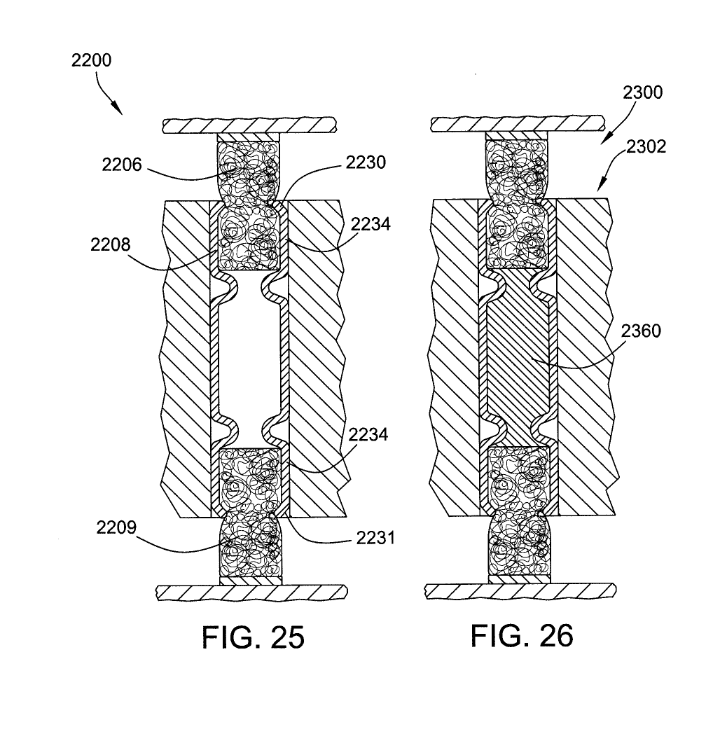

Referring to FIG. 25, the connector 2200 may be similar to connector 1800 except that the sleeve 2208 may have another embodiment of an element retention feature. The element retention feature may be a first end portion 2230 and a second end portion 2231. The first end portion 2230 and second end portion 2231 may have a smaller size than the main portion 2234. The first and second end portions 2230, 2231 may help to retain the elements 2206, 2209 within the sleeve 2208. In another embodiment, the sleeve may include the first end portion, but not the second end portion. In another embodiment, the sleeve may include the second end portion, but not the first end portion. In other embodiments, the connector may use any of the element retention features described herein, and/or any of the sleeve retention features described herein, as appropriate.

Referring to FIG. 26, the connector 2300 may be similar to connector 2200 except that the contact 2302 may include a conductive material 2360, as described herein. In other embodiments, the connector may use any of the element retention features described herein, and/or any of the sleeve retention features described herein, as appropriate.

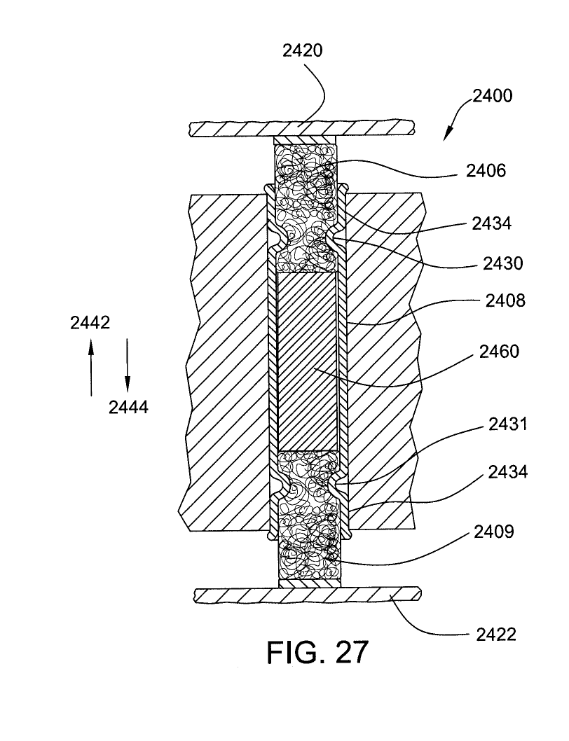

Referring to FIG. 27, the connector 2400 may be similar to connector 1900 except that the sleeve 2408 may have another embodiment of an element retention feature. The element retention feature may be a first reduced portion 2430 and a second reduced portion 2431. The first reduced portion 2430 and the second reduced portion 2431 may have a smaller size than the main portion 2434. The first and second reduced portions 2430, 2431 may help to retain the elements 2406, 2409 within the sleeve 2408. However, the reduced portions 2430, 2431 may allow the elements 2406, 2409 and the conductive material 2460 to move in directions 2442, 2444. Thus, the elements 2406, 2409 and the conductive material 2460 can accommodate height differences of the components 2420, 2422. In another embodiment, the sleeve may include the first reduced portion, but not the second reduced portion. In another embodiment, the sleeve may include the second reduced portion, but not the first reduced portion. In other embodiments, the connector may use any of the sleeve retention features described herein, as appropriate.

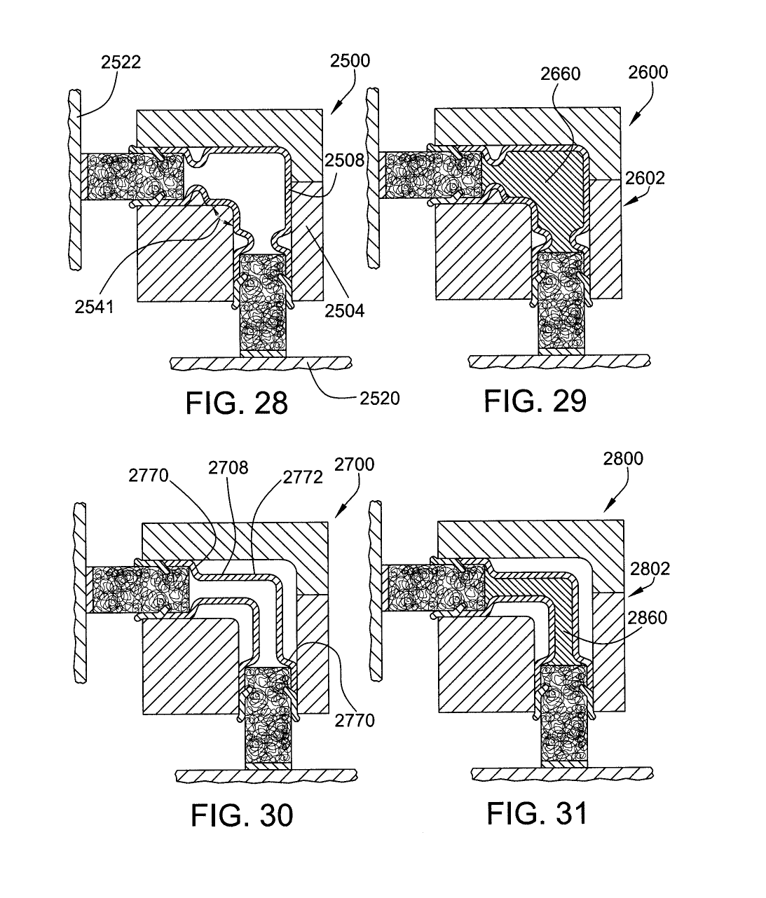

Referring to FIG. 28, the connector 2500 may be similar to connector 1800 except that the sleeve 2508 may be bent at an angle 2541. In one embodiment, the angle 1241 may be approximately 90 degrees. The contact substrate 2504 may be one or more components in order to facilitate assembly. The electrical connector 2500 may provide an electrical connection between a first components 2520, such as a printed circuit board, and a second component 2522, such as a printed circuit board. In other embodiments, the connector may use any of the element retention features described herein, as appropriate.

Referring to FIG. 29, the connector 2600 may be similar to connector 2500 except that the contact 2602 may include a conductive material 2660, as described herein. In other embodiments, the connector may use any of the element retention features described herein, as appropriate.

Referring to FIG. 30, the connector 2700 may be similar to connector 2500 except that the intermediate portion 2772 of the sleeve 2708 may be the same size as the narrowed portions 2770. In other embodiments, the connector may use any of the element retention features described herein, as appropriate.

Referring to FIG. 31, the connector 2800 may be similar to connector 2700 except that the contact 2802 may include a conductive material 2860, as described herein. In other embodiments, the connector may use any of the element retention features described herein, and/or any of the sleeve retention features described herein, as appropriate.

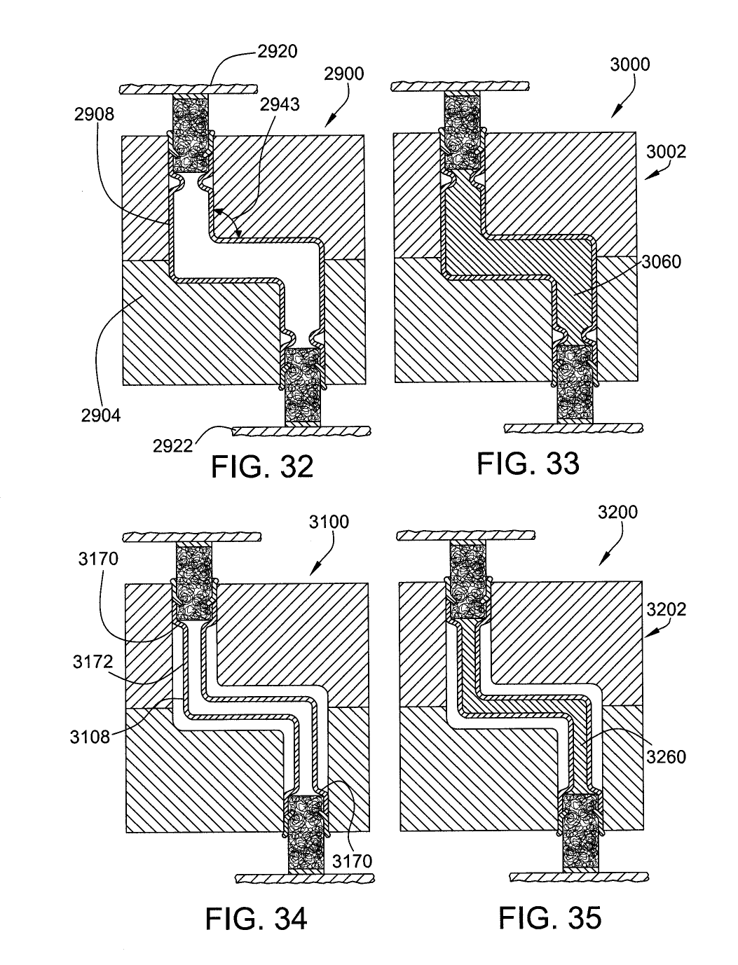

Referring to FIG. 32, another embodiment of a connector is shown. The connector 2900 may be used for longer distances and to connect contact surfaces which are offset. The connector 2900 may be similar to connector 2500 except that the sleeve 2908 may be bent a second angle 2943. In one embodiment, the angle 2943 may be approximately 90 degrees. The contact substrate 2904 may be one or more components in order to facilitate assembly. The electrical connector 2900 may provide an electrical connection between a first component 2920, such as a printed circuit board, and a second component 2922, such as a printed circuit board. In other embodiments, the connector may use any of the element retention features described herein, as appropriate.

Referring to FIG. 33, the connector 3000 may be similar to connector 2900 except that the contact 3002 may include a conductive material 3060, as described herein. In other embodiments, the connector may use any of the element retention features described herein, as appropriate.

Referring to FIG. 34, the connector 3100 may be similar to connector 2900 except that the intermediate portion 3172 of the sleeve 3108 may be the same size as the narrowed portions 3170. In other embodiments, the connector may use any of the element retention features described herein, as appropriate.

Referring to FIG. 35, the connector 3200 may be similar to connector 3100 except that the contact 3202 may include a conductive material 3260, as described herein. In other embodiments, the connector may use any of the element retention features described herein, as appropriate.

The wadded wire element may be any suitable material, such as, a metal. For example, the wadded wire element may be molybdenum, tungsten, copper, or copper alloy. The wire may be plated with any noble or precious metal that is used in a contact interface, such as, gold, palladium nickel, rhodium, or platinum. The sleeve may be any conductive material, such as, a metal. For example, the sleeve may be copper, copper alloy, or aluminum. The sleeve may be plated with any of the materials noted above for the wadded wire element. The sleeve may have an underplating, such as, nickel. As another example, the sleeve may be a zincated aluminum with a nickel underplating and a gold plating.

The contact substrate may be molded or machined with the openings. The contact substrate may be any suitable material, such as, plastic, fiberglass, or metal. The plastic may be: a liquid crystal polymer, such as the product sold by Hoechst Celanese Corporation under the trade name Vectra; a polyethermide, such as the product sold by GE Plastics under the trade name Ultem; a polyphthalamide, such as the product sold by Solvay Advanced Polymers under the trade name Amodel; a blend of polyphenylene oxide and polystyrene, such as the product developed by GE Plastics and sold under the trade name Noryl; a polyphenylene sulfide, such as the product sold by Phillips Petroleum under the trade name Ryton; or a polybutylene terephthalate. The fiberglass may be FR-4, or G-10. The metal may be an anodized aluminum (which becomes an insulator after the anodizing process).

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. An electrical connector comprising a substrate, the substrate including a first surface and a second surface, the substrate including an opening, the opening extends from the first surface to the second surface, a sleeve, the sleeve positioned in the substrate opening, the sleeve including a first portion, a second portion, and a third portion, the sleeve including an opening, the first portion of the sleeve extends beyond the first surface of the substrate, a wadded wire element, the wadded wire element positioned in the sleeve opening, the wadded wire element extends beyond the first surface of the substrate.

2. The electrical connector as in claim 1 wherein the wadded wire element extends beyond the second surface of the substrate.

3. The electrical connector as in claim 1 wherein the third portion of the sleeve extends beyond the second surface of the substrate.

4. The electrical connector as in claim 1 wherein the sleeve includes a sleeve retention feature.

5. The electrical connector as in claim 4 wherein the first portion of the sleeve is larger than the second portion.

6. The electrical connector as in claim 5 wherein the third portion of the sleeve is larger than the second portion.

7. The electrical connector as in claim 4 wherein the first portion of the sleeve is larger than the substrate opening at the first surface of the substrate.

8. The electrical connector as in claim 7 wherein the third portion of the sleeve is larger than the substrate opening at the second surface of the substrate.

9. The electrical connector as in claim 1 wherein the sleeve includes a retention feature for the wadded wire element.

10. The electrical connector as in claim 1 further comprising a second wadded wire element, the wadded wire element is positioned in the first portion of the sleeve, the second wadded wire element is positioned in the third portion of the sleeve.

11. The electrical connector as in claim 10 wherein a conductive material is positioned in the opening in the sleeve between the wadded wire element and the second wadded wire element.

12. The electrical connector as in claim 10 wherein the first portion of the sleeve is at an angle to the third portion of the sleeve.

13. An electrical connector comprising a substrate, the substrate including a first surface and a second surface, the substrate including an opening, the opening extends from the first surface to the second surface, a sleeve, the sleeve is positioned in the substrate opening, the sleeve including a first portion and a second portion, the sleeve including an opening, a wadded wire element, the wadded wire element positioned in the sleeve opening, the wadded wire element extends beyond the first surface of the substrate, the second portion of the sleeve extends beyond the wadded wire element.

14. The electrical connector as in claim 13 wherein the second portion of the sleeve extends beyond the second surface of the substrate.

15. The electrical connector as in claim 13 wherein the second portion of the sleeve is closed.

16. The electrical connector as in claim 13 wherein the second portion of the sleeve is smaller than the first portion of the sleeve.

17. The electrical connector as in claim 13 wherein the sleeve includes a retention feature for the wadded wire element.

18. The electrical connector as in claim 13 wherein the second portion includes a conductive material in the sleeve.

19. The electrical connector as in claim 13 wherein the second portion is at an angle to the first portion.

20. The electrical connector as in claim 1 further comprising a second wadded wire element, the sleeve includes a third portion, the second wadded wire element is positioned in the third portion.

21. An electrical connector comprising a substrate, the substrate including a first surface and a second surface, the substrate including an opening, the opening extends from the first surface to the second surface, a sleeve, the sleeve is positioned in the substrate opening, the sleeve including a first portion and a second portion, the sleeve including an opening, a wadded wire element, the wadded wire element positioned in the sleeve opening, the wadded wire element extends beyond the first surface of the substrate, the sleeve including a wadded wire element retention feature, the retention feature is a detent.

22. An electrical connector comprising a substrate, the substrate including a first surface and a second surface, the substrate including an opening, the opening extends from the first surface to the second surface, a sleeve, the sleeve positioned in the substrate opening, the sleeve including a first portion, a second portion, and a third portion, the sleeve including an opening, a wadded wire element, the wadded wire element positioned in the sleeve opening, the wadded wire element extends beyond the first surface of the substrate, the first portion of the sleeve is larger than the second portion, the first portion retains the sleeve in the opening.

23. An electrical connector comprising a substrate, the substrate including a first surface and a second surface, the substrate including an opening, the opening extends from the first surface to the second surface, a sleeve, the sleeve is positioned in the substrate opening, the sleeve including a first portion and a second portion, the sleeve including an opening, a wadded wire element, the wadded wire element positioned in the sleeve opening, the wadded wire element extends beyond the first surface of the substrate, the sleeve including a sleeve element retention feature, the retention feature is a gap in the sleeve.

24. An electrical connector comprising a substrate, the substrate including an opening, a sleeve, the sleeve is positioned in the substrate opening, the sleeve including a first portion and a second portion, the sleeve including an opening, a wadded wire element, the wadded wire element positioned in the sleeve opening, the wadded wire element extends beyond the first portion of the sleeve, the second portion of the sleeve is soldered to the substrate opening.
